(19) United States
(12) Patent Application Publication
(10) Pub. No.: US 2026/0209554 A1
(43) Pub. Date: Jul. 23, 2026

(54) PLANARIZATION SOLUTION FOR ABRASIVE-FREE COPPER PLANARIZATION

(71) Applicant: CHEMPOWER CORPORATION, Beaverton, OR (US)

(72) Inventors: Sudhanshu Misra, Camas, WA (US); Suryadevara Babu, Portland, OR (US); Nikunjkumar R. Visaveliya, Lyndhurst, NJ (US); Matthias Stender, Phoenix, AZ (US); Changxue Wang, Minneapolis, MN (US); Mykola Abramchuk, Hillsboro, OR (US)

(21) Appl. No.: 19/452,095

(22) Filed: Jan. 16, 2026

Related U.S. Application Data
(60) Provisional application No. 63/746,603, filed on Jan. 17, 2025.

(51) Int. Cl. C09G 1/04; H10P 52/40; H10P 70/00

(52) U.S. Cl. CPC C09G 1/04; H10P 52/403; H10P 70/277

(57) ABSTRACT

Examples are disclosed that relate to a planarization solution for abrasive-free planarization. The planarization solution comprises a hydrolyzing agent, a first chelator, and a second chelator.

### CROSS REFERENCE TO RELATED APPLICATIONS

This application claims priority to U.S. Provisional Application 63/746,603, entitled “PLANARIZATION SOLUTION FOR ABRASIVE-FREE COPPER PLANARIZATION” and filed Jan. 17, 2025, the entirety of which is hereby incorporated herein by reference for all purposes.

### BACKGROUND

Chemical mechanical planarization (CMP) is commonly used in integrated circuit fabrication processes to smooth surfaces, such as that of a semiconductor substrate, by removal of material using a combination of chemical and mechanical forces. A typical CMP process involves using an abrasive and a chemical slurry that can be corrosive to the material being removed, in combination with a polishing pad. The substrate and polishing pad are pressed together, and rotated relative to one another with non-concentric axes of rotation. The combination of the force and slurry removes areas of the substrate with a higher topology compared to areas with a lower topology, thereby smoothing the surface.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to solutions for performing abrasive-free chemical planarization. One example provides a planarization solution for abrasive-free planarization. The planarization solution comprises a hydrolyzing agent, a first chelator, and a second chelator.

Another example provides a method of planarizing a substrate comprising copper. The method comprises removing copper from the substrate by contacting the substrate with a chemically functionalized planarization pad and a planarization solution. The planarization solution comprises a hydrolyzing agent, a first chelator, and a second chelator.

Another example provides a chemical planarization system. The chemical planarization system comprises a chemically functionalized planarization pad, a platen configured to support the chemically functionalized planarization pad, and a substrate holder configured to hold a substrate against a surface of the chemically functionalized planarization pad. The chemical planarization system further comprises a planarization solution introduction system comprising a planarization solution. The planarization solution introduction system is configured to introduce the planarization solution onto the chemically functionalized planarization pad. The planarization solution comprises a hydrolyzing agent, a first chelator, and a second chelator.

### BRIEF DESCRIPTION OF THE FIGURES

FIG. 1 shows a block diagram of an example abrasive-free chemical planarization system.

FIG. 2 shows a plot of a removal rate of a blanket copper film for a first example abrasive-free planarization solution.

FIG. 3 shows a plot of a removal rate of a blanket copper film for a second example abrasive-free planarization solution.

FIGS. 4-7 show plots of step heights of features of patterned copper/silicon oxide (TEOS (tetraethylorthosilicate)) substrates after planarizing using the first example abrasive-free planarization solution of FIG. 2 and the second example abrasive-free planarization solution of FIG. 3, and using a functionalized planarization pad.

FIGS. 8-9 show plots of step heights of a patterned copper/silicon oxide substrate after processing using the first example abrasive-free planarization solution of FIG. 2 and the second example abrasive-free planarization solution of FIG. 3, and using a conventional CMP pad.

FIG. 10 shows a flow diagram of an example method of planarizing a substrate comprising copper.

### DETAILED DESCRIPTION

While current methods of CMP find use in a wide variety of device fabrication contexts, current CMP methods also pose various drawbacks. For example, current CMP processes are relatively dirty compared to other fabrication processes, due at least in part to the use of conditioner chemicals, as well as the abrasive slurry and pad that mechanically abrade the material during planarization. Defects generated by CMP can be large yield loss contributors to fabs. Defects and scratches generated during CMP may largely originate from the mechanical components in the process, such as the abrasives in the slurry, the force of the pad against the substrate, pad conditioning, and tribological aspects of the process. Further, the slurry contains abrasives that can scratch device layers, thereby creating pits and leaving residues that can become killer defects. Additionally, pad debris is generated during polish and pad conditioning. Such pad debris can create particles and agglomerates that contaminate the substrate being processed. Also, the force of the pad against the wafer can cause pad deformation. This can result in shear stresses at interfaces from intimate contact with the substrate and relative motion between the substrate and pad. Further, CMP processes may not be predicable, and thus may be dominated by trial-and-error approaches, rather than analytical approaches. Further still, the handling, delivering and stabilization of slurries can pose difficulties for fabrication facilities due to solid content. This can increase facilities maintenance costs. As a result, conventional CMP processes can require redundancy in deposition and over polishing, which can lead to wasted resources, increased costs, and lower productivity.

As one example of a material that is planarized using CMP, copper is used as a wiring metal in the back end of the line of semiconductor chips. Since copper is a very soft metal, it is prone to scratches and other defects.

Accordingly, examples are disclosed herein that relate to abrasive-fee planarization solutions comprising chelators and other additives configured to minimize scratch defects and optimize performance. Briefly, the disclosed examples utilize an abrasive-free planarization chemistry configured to be used in the planarization of at least copper. The term “abrasive-free” indicates a planarization chemistry without a mechanically abrasive solid component for removing substrate material by abrasion. The disclosed solutions comprise a hydrolyzing agent and two or more chelators. The disclosed solutions further can comprise additives, such as a corrosion inhibitor/topography additive. For example, the two or more chelators can comprise glycine, oxalic acid, citric acid, maleic acid, glutamic acid, L-alanine, any other suitable acid, or an amino acid. Further, a planarization solution comprising glycine and oxalic acid can comprise a corrosion inhibitor/topology additive such as ammonium dodecyl sulfate (ADS), diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

The inventors have found that using glycine and oxalic acid as a dual chelator system in a planarization solution, along with a functionalized abrasive-free planarization pad, leads to unexpected results. For example, abrasive-free planarization solutions with oxalic acid alone or glycine alone as chelators showed scratch defects. However, when combined together, scratch defects were not observed, even though each chelator alone showed scratch defects.

Further, the use of one or more of the above listed example corrosion inhibitors, rather than benzoyltriazole (BTA) or other azoles (which are frequently described for use as a corrosion inhibitor in CPM) can provide an optimized solution for the abrasive-free planarization of copper. For example, by combining glycine and oxalic acid at varying concentrations as chelators in the example copper polishing solutions, along with the addition of ADS in some examples, abrasive free planarization of copper with optimized performance in terms of elimination of scratch defects, minimizing surface haze, low removal rate non-uniformity, and optimizing planarization efficiency, was achieved when using functionalized abrasive-free planarization pads. As another example, by combing the disclosed solution comprising two or more chelators with the one of the above listed corrosion inhibitors, abrasive free planarization of copper with optimized performance in terms of improving surface smoothness and/or uniformity of removal (for example, by avoiding dishing) can be achieved.

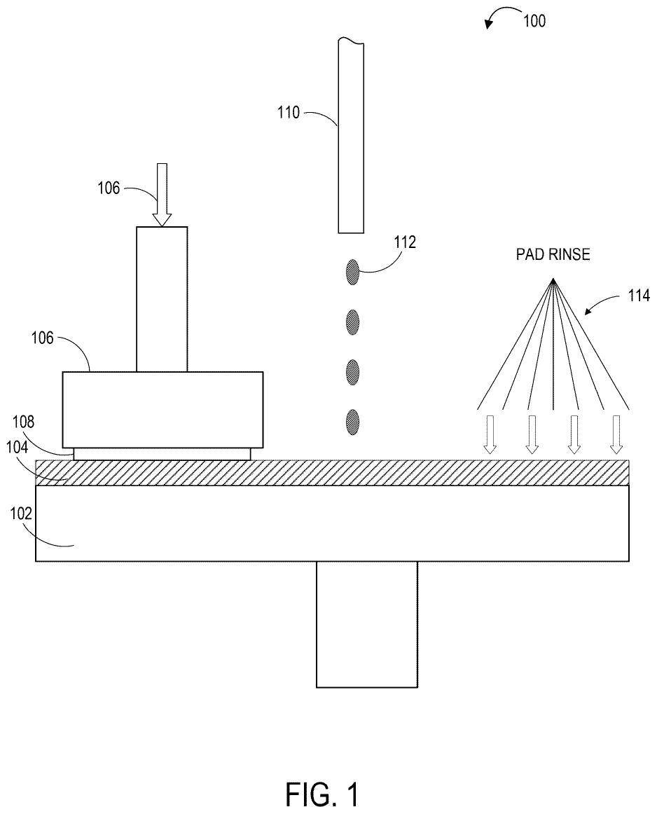

Prior to discussing the disclosed examples of abrasive-free planarization solutions for copper planarization, FIG. 1 shows a schematic depiction of an example chemical planarization system 100 according to the present disclosure. System 100 comprises a platen 102 that supports a pad 104. In some examples, the pad 104 can comprise a chemically functionalized planarization pad that comprises one or more of carboxylic acid groups, sulfonyl groups, or amine groups bonded to the chemically functionalized planarization pad as functional groups. In other examples, any other suitable pad can be used. The system 100 further includes a substrate holder 106 configured to hold a substrate 108 against the surface of the pad 104, and a planarization solution introduction system 110 for introducing a planarization solution 112 onto the pad 104. The system 100 further may comprise a pad rinsing system 114 configured to rinse possible contaminant materials from the pad 104, such as complexed materials that have been removed from the surface of the substrate 108. Pad rinsing system 114 also may be used to clean the pad between using different planarization solution chemistries, as described below. Other components (not shown) that optionally may be incorporated into system 100 include, but are not limited to, a spent solution recovery system, a materials recirculation system (e.g., for recirculating the planarization solution in a closed loop process), and a species stripping system.

In conventional CMP processes, the substrate holder pushes the substrate against a polishing pad supported on a platen, and the pad and the substrate are rotated relative to one another in a non-concentric pattern. In such conventional processes, relatively high rates of rotations are used, such as between 40-100 revolutions per minute (rpm). Further, the substrate is pushed against the pad with a relatively high pressure, such as in a range of 1-4 pounds per square inch. In contrast, a lighter pressure can be used in the disclosed examples, including but not limited to pressures in the range of 0.25 to 0.75 pounds per square inch. The lighter pressure may avoid distortion of the pad shape, and may reduce shear stresses compared to conventional CMP processes. Likewise, a slower rate of rotation may be used in the disclosed examples than with conventional CMP processes, as the rotational motion is not used for abrasion. Instead, rotation of the platen 102 helps to distribute planarization fluid across the pad 104. Any suitable rate of rotation may be used. Examples include rates in a range of 0-60 rpm. More specific examples include rates of 5-30 rpm. As mentioned above, the rate of rotation may be lower than a rate at which a platen rotates in a conventional CMP process, as the rotational motion is not being used in the examples herein to abrade material from a substrate. In other examples, one or more parameters outside of the ranges above can be used where suitable. Further, it will be understood that many different configurations and designs are possible for a variety of platform types (e.g., rotary, linear or belt style, vertically or horizontally oriented, rollers, and/or hollow fibers).

The inventors have found that the use of two or more chelators, along with a hydrolyzing agent, in an abrasive free planarization solution can provide for reduced scratching and higher removal rates than the use of single chelators in abrasive-free planarization solutions. Any suitable chelators can be used as a combination of two or more chelators in an abrasive free planarization solution. Example chelators include oxalic acid, glycine, citric acid, maleic acid, glutamic acid, L-alanine, any other suitable acid, and an amino acid. Any suitable hydrolyzing agent can be used to hydrolyze a substrate material (e.g., by oxidation and dissolution). An example of a suitable hydrolyzing agent is hydrogen peroxide (H₂O₂). In some examples, a pH of the planarization solution is within a range of 1 to 13. In other examples, the pH of the planarization solution is within a range of 3 to 9. The pH of the planarization solution can be adjusted using any suitable pH adjusting agent. Suitable pH adjusting agents include ammonium hydroxide, tetrabutylammonium hydroxide, and potassium hydroxide.

TABLE 1 below summarizes the results of experiments using oxalic acid and glycine alone and together as chelators in an abrasive-free planarization solution with a hydrolyzing agent (hydrogen peroxide (H₂O₂)). The experimental data in TABLE 1 below was acquired using 4 cm×4 cm copper blanket coupons with a nine-inch polishing pad using a Bruker CETR polishing system. The planarization pad was a polyurethane pad functionalized with carboxylic functional groups bonded to the polyurethane.

TABLE 1

| | Scratch | Removal | Non- |
|---|---|---|---|
| | Observa- | Rate | Uniformity |
| Formulation | tions | [A/min] | [%] |
| 0.11% oxalic acid, 3% H₂O₂, pH 3 | Yes | 4310 | 5.4 |
| 0.5% glycine, 1% H₂O₂, pH 3 | Yes | 5357 | 4 |
| 0.11% oxalic acid, 0.5% glycine, | Yes | 1655 | 3.4 |
| 1% H₂O₂, pH 3 | | | |
| 0.11% oxalic acid, 0.5% glycine, | No | 5303 | 1.3 |
| 1% H₂O₂, pH 5 | | | |

The data of TABLE 1 shows that the combination of glycine and oxalic acid leads to the overall best performance by eliminating scratch defects while providing for an unexpectedly high removal rate (for example, up to 15000 angstroms per minute) with the best non-uniformity of the solutions tested in this experiment.

TABLE 2 below shows data representing how the addition of ADS to a formulation with both glycine and oxalic acid leads to complete elimination of any chemical etch on copper.

TABLE 2

| ADS Concentration [mM] | SER [A/min] |
|---|---|
| 0.1 | 1727 |
| 0.2 | 632 |
| 0.3 | 33 |
| 1 | 4 |
| 2 | 0 |
| 3 | 0 |

More particularly, the data in TABLE 2 shows that with an ADS concentration of higher than 1 millimolar (mM), the static etch rate (SER) of copper is completely shut off.

TABLE 3 below shows formulations of example abrasive-free planarization solutions with 1 mM and 3 mM ADS for 200 mm wafer planarization experiments.

TABLE 3

| Process | |
|---|---|
| Step | Formulation |
| P1 | 0.11% oxalic acid, 0.5% glycine, 1 mM ADS, 1% H₂O₂, pH 5 |
| P2 | 0.11% oxalic acid, 0.5% glycine, 3 mM ADS, 1% H₂O₂, pH 5 |
| P1 | 0.11% oxalic acid, 0.5% glycine, 1.5 mM ADS, 1% H₂O₂, pH 6 |
| P2 | 0.11% oxalic acid, 0.5% glycine, 3 mM ADS, 1% H₂O₂, pH 6 |

The only difference between the first and second solutions of TABLE 3 is the ADS concentration. Similarly, the only difference between the third and fourth solutions of TABLE 3 is the ADS concentration. The difference between the first two solutions and the second two solutions in TABLE 3, is the solution pH the data was collected at. Additionally, the first P1 solution comprises a different ADS concentration than the second P1 solution.

The performance of the first two solutions of TABLE 3 can be seen below in TABLE 4. Blanket RR is removal rate in angstroms per minute. WIWNU is within-wafer non-uniformity expressed as a percentage.

TABLE 4

| | Blanket RR [A/min] | WIWNU |
|---|---|---|
| P1 Step | 4677 | 3.4 |
| P2 Step | 2710 | 5.2 |

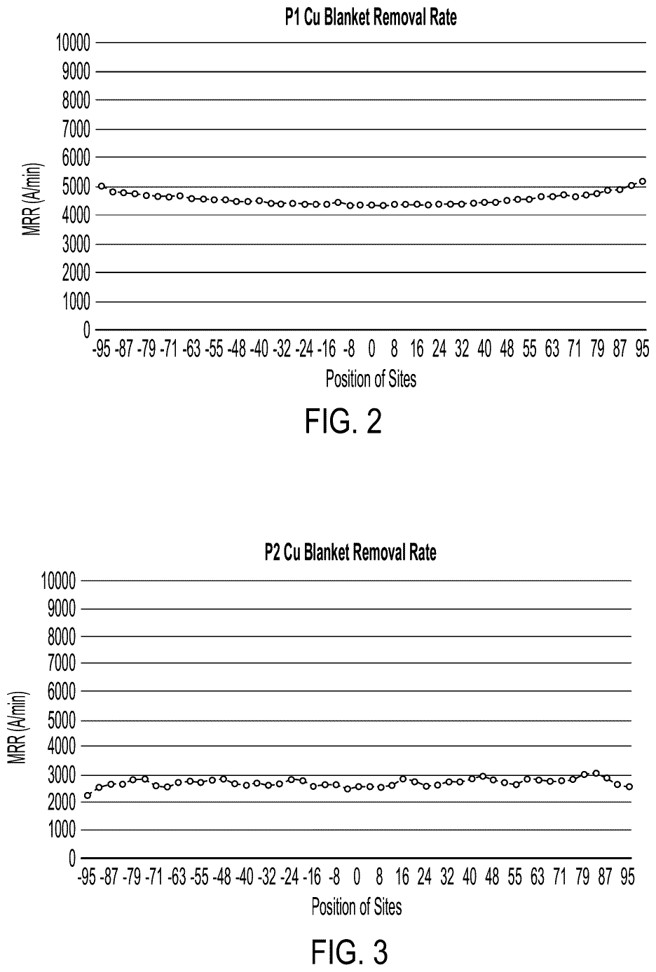

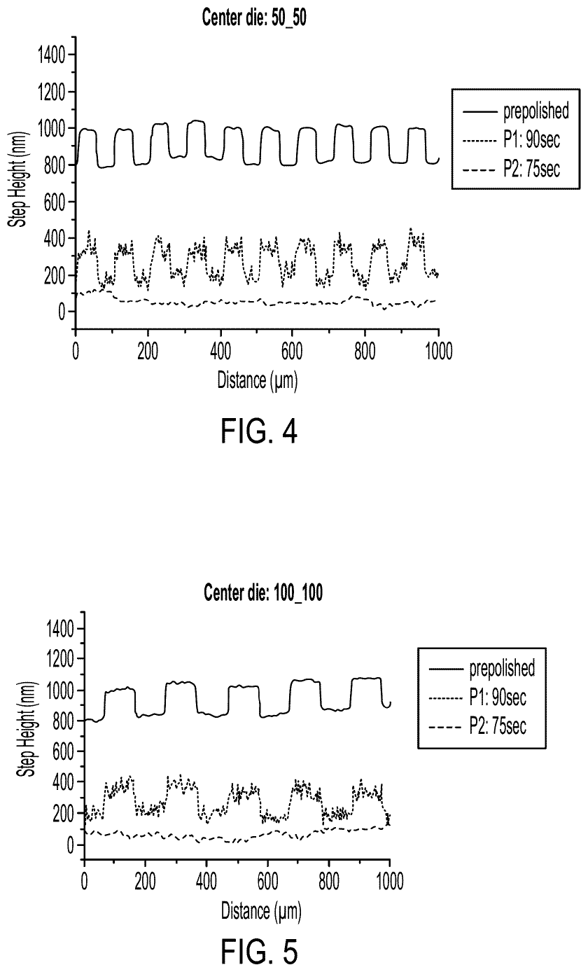

Both of the optimized solutions of TABLE 4 were able to provide remarkably flat removal profiles on 200 mm copper blanket wafers. Additionally, the optimized solutions of TABLE 4 provided flat removal profiles on 300 mm copper blanket wafers. FIG. 2 shows removal rate, in angstroms per minute, as a function of radial position on a wafer for solution P1 of TABLE 4. FIG. 3 shows removal rate, in angstroms per minute as a function of radial position on a wafer for solution P2 of TABLE 4.

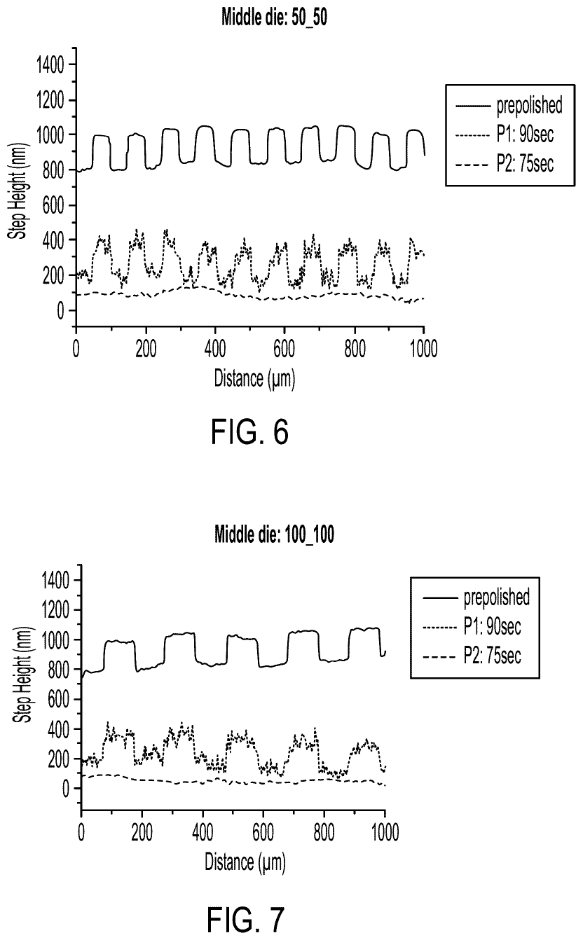

Next, MIT 754 type Cu/TEOS patterned wafers were planarized with the P1 and P2 solutions. FIGS. 4-7 show the result of these experiments, and illustrate good planarization for both solutions at both center die and middle die. The solid lines of FIGS. 4-7 show the step height (nm) of a prepolished wafer as a function of distance (μm). The dotted lines of FIGS. 4-7 show the step height (nm) of the wafer as a function of distance (μm) after performing planarization with P1 for 90 seconds. The dashed lines of FIGS. 4-7 show the step height (nm) of the wafer as a function of distance (μm) after performing planarization with P2 for 75 seconds. The term 50_50 indicates 50 nm wide copper lines separated by 50 nm spacers. The term 100_100 indicates 100 nm wide copper lines separated by 100 nm spacers. This data shows that the flat removal profiles from the copper blanket wafers also translate to uniform topography correction across pattern wafers.

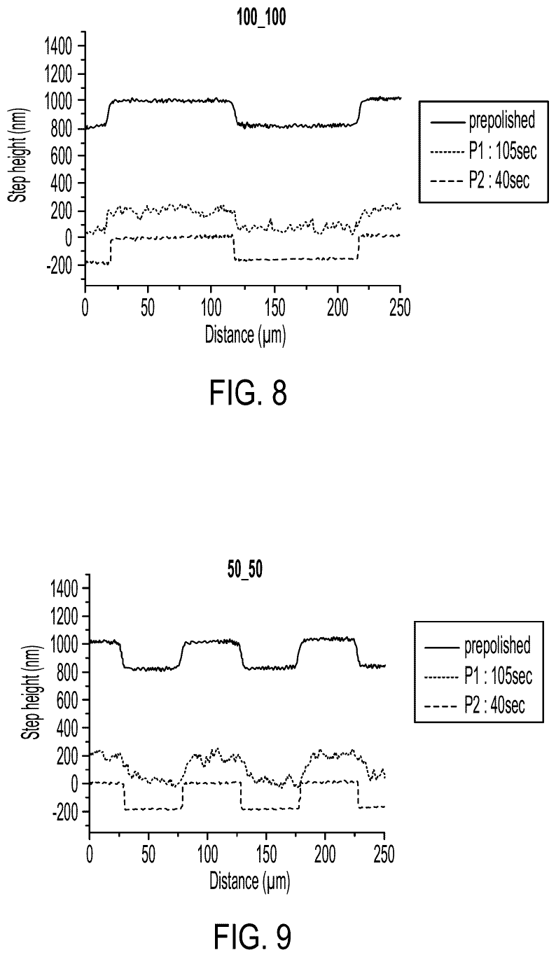

It is noted that that the planarization solution formulations of the present disclosure perform best in combination with a chemically functionalized pad, such as a polyurethane pad functionalized with carboxylic acid groups bonded to the polyurethane. Examples of such functionalized pads include those disclosed in U.S. Pat. No. 11,545,365, titled CHEMICAL PLANARIZATION, and U.S. Patent Application Publication No. 2024/0391050, titled PADS FOR CHEMICAL PLANARIZATION. The disclosures of each of these applications are hereby incorporated by reference. If the P1 and P2 solutions of this invention are used in combination with an industry standard pad (e.g., an IC1000 pad from DuPont de Nemours, Inc. of Wilmington, DE), no topography correction is observed, as shown in FIGS. 8-9. The solid lines of FIGS. 8-9 show the step height (nm) of a prepolished wafer as a function of distance (μm). The dotted lines of FIGS. 8-9 show the step height (nm) of the wafer as a function of distance (μm) after performing planarization with P1 for 105 seconds. The dashed lines of FIGS. 8-9 show the step height (nm) of the wafer as a function of distance (μm) after performing planarization with P2 for 40 seconds.

As described above, the planarization solution can include one or more corrosion inhibitors. The corrosion inhibitors can improve surface smoothness and the uniformity of the substrates, for example, by improving dishing, after planarizing according to the present disclosure. Any suitable corrosion inhibitor or combination of corrosion inhibitors can be used. Example corrosion inhibitors include ammonium dodecyl sulfate (ADS), diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, and 1,2,4-triazole.

TABLE 5 below summarizes the results of experiments using different corrosion inhibitors with respect to improved surface smoothness. The experimental data in TABLE 5 below was acquired using wafers planarized with the P2 solution at pH 6, as described above in TABLE 3.

TABLE 5

| | | Surface | | Surface |
|---|---|---|---|---|
| | | Smoothness | | Smoothness |
| Amount | Sa, nm | Improvement | Sq, nm | Improvement |

Imidazole

| 0 | | 3.3 | — | 4.7 | — |
|---|---|---|---|---|---|
| 50 | ppm | 2.6 | 21% | 3.3 | 30% |
| 100 | ppm | 2.7 | 18% | 3.5 | 25% |

3-amino-1,2,4-triazole

| 0 | | 2.3 | — | 2.8 | — |
|---|---|---|---|---|---|
| 1 | ppm | 1.7 | 26% | 2.2 | 21% |
| 10 | ppm | 1.6 | 30% | 2.1 | 25% |

1,8-Diazabicyclo[5.4.0]undec-7-ene

| 0 | | 2.0 | — | 2.7 | — |
|---|---|---|---|---|---|
| 25 | ppm | 1.3 | 35% | 1.7 | 37% |

Benzotriazole

| 0 | | 2.6 | — | 3.2 | — |
|---|---|---|---|---|---|
| 0.05 | ppm | 1.5 | 42% | 1.8 | 44% |
| 0.20 | ppm | 0.5 | 81% | 0.7 | 78% |
| 0.60 | ppm | 0.9 | 65% | 1.2 | 62% |

5-Methyl-1H-Benzotriazole

| 0 | | 2.7 | — | 3.9 | — |
|---|---|---|---|---|---|
| 0.1 | ppm | 2.2 | 18% | 2.8 | 28% |
| 0.5 | ppm | 1.2 | 55% | 1.5 | 61% |

3,5-Diamino-1,2,4-Triazole

| 0 | | 2.7 | — | 3.9 | — |
|---|---|---|---|---|---|
| 10 | ppm | 1.5 | 44% | 2.1 | 46% |
| 50 | ppm | 1.8 | 33% | 2.4 | 38% |

Adenine

| 0 | | 3.9 | — | 5.3 | — |
|---|---|---|---|---|---|
| 1 | ppm | 2.4 | 38% | 3.0 | 43% |
| 3 | ppm | 1.0 | 74% | 1.2 | 77% |

1H-Purine

| 0 | | 3.5 | — | 4.7 | — |
|---|---|---|---|---|---|
| 2 | ppm | 2.2 | 37% | 2.7 | 42% |
| 5 | ppm | 1.5 | 57% | 2.0 | 57% |

3-Amino-5-methylthio-1H-1,2,4-triazole

| 0 | | 4.8 | — | 6.7 | — |
|---|---|---|---|---|---|
| 10 | ppm | 2.1 | 56% | 3.0 | 55% |
| 100 | ppm | 1.7 | 64% | 2.1 | 69% |
| 200 | ppm | 1.4 | 71% | 1.8 | 73% |
| 500 | ppm | 1.8 | 62% | 2.4 | 64% |

1,2,4-Triazole

| 0 | | 3.9 | — | 5.3 | — |
|---|---|---|---|---|---|
| 10 | ppm | 2.1 | 46% | 2.7 | 49% |

Diammonium Phosphate

| 0 | | 2.7 | — | 3.9 | — |
|---|---|---|---|---|---|
| 10 | ppm | 1.7 | 37% | 2.7 | 31% |

Sa = Arithmetic Mean Height of the Surface,
Sq = Root Mean Square Height of the Surface

More particularly, the data in TABLE 5 shows that with the addition of the corrosion inhibitors included in TABLE 5 to the P2 solution, the surface smoothness of the wafer can be improved up to 81% (0.20 ppm benzotriazole).

TABLE 6 below summarizes the results of experiments using different corrosion inhibitors with respect to improved dishing of the wafer after performing planarization according to the present disclosure. The experimental data in TABLE 6 below was acquired using wafers planarized with the P2 solution at pH 6, as described above in TABLE 3.

TABLE 6

| | | |
|---|---|---|
| Amount | Average Dishing, nm | Dishing Improvement |

3-amino-1,2,4-triazole

| | | |
|---|---|---|
| 0 | 77.2 | — |

| | | | |
|---|---|---|---|
| 10 | ppm | 52.5 | 32% |

Adenine

| | | |
|---|---|---|
| 0 | 77.2 | — |

| | | | |
|---|---|---|---|
| 1 | ppm | 60 | 22% |
| 3 | ppm | 41.3 | 46% |
| 5 | ppm | 38 | 51% |

3-Amino-5-methylthio-1H-1,2,4-triazole

| | | |
|---|---|---|
| 0 | 77.2 | — |

| | | | |
|---|---|---|---|
| 200 | ppm | 61.6 | 20% |

More particularly, the data in TABLE 6 shows that with the addition of the corrosion inhibitors included in TABLE 6 to the P2 solution, the dishing of the wafer can be improved up to 51% (5 ppm adenine).

In addition to the corrosion inhibitors of TABLE 5 improving the surface smoothness of the wafer, L-alanine can be used as a chelator, rather than glycine, to improve the surface smoothness of the wafer. TABLE 7 below summarizes the results of experiments using different concentrations of L-alanine with respect to improved surface smoothness. The experimental data in TABLE 7 below was acquired using wafers planarized with the P2 planarization solution at pH 6, which comprises glycine, as described above in TABLE 3, and wafers planarized using L-alanine, rather than glycine, in the P2 solution at pH 6.

TABLE 7
L-Alanine replacing Glycine as a chelator

| | | Surface | | Surface |
|---|---|---|---|---|
| | | Smoothness | | Smoothness |
| Amount | Sa, nm | Improvement | Sq, nm | Improvement |
| Glycine 0.5% | 5.5 | — | 7.0 | — |
| L-Alanine 1.8% | 2.1 | 62% | 2.7 | 61% |
| L-Alanine 2.0% | 2.0 | 64% | 2.6 | 63% |

More particularly, the data in TABLE 7 shows that using 1.8% to 2.0% L-alanine in the P2 solution, rather than 0.5% glycine, can improve the surface smoothness of the wafer by 62% to 64%.

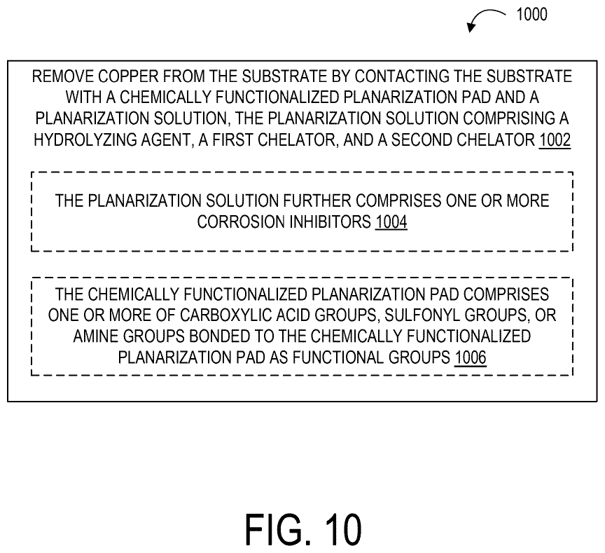

FIG. 10 shows a flow diagram depicting an example method 1000 of planarizing a substrate comprising copper. The dashed lines of FIG. 10 represent optional steps of method 1000.

At 1002, method 1000 comprises removing copper from the substrate by contacting the substrate with a chemically functionalized planarization pad and a planarization solution. The planarization solution comprises a hydrolyzing agent, a first chelator, and a second chelator. Any suitable hydrolyzing agent can be used to hydrolyze a substrate material (e.g., by oxidation and dissolution). An example suitable hydrolyzing agent is hydrogen peroxide (H₂O₂). Any suitable chelator can be used as the first chelator and the second chelator. Examples of suitable chelators include glycine, oxalic acid, citric acid, maleic acid, glutamic acid, L-alanine, any other suitable acid, and an amino acid.

In some examples, at 1004, the planarization solution further comprises one or more corrosion inhibitors. Any suitable corrosion inhibitor or combination of corrosion inhibitors can be used. Examples of suitable corrosion inhibitors include ammonium dodecyl sulfate (ADS), diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, and 1,2,4-triazole. In other examples, the corrosion inhibitor can be omitted.

In some examples, at 1006, the chemically functionalized planarization pad comprises one or more of carboxylic acid groups, sulfonyl groups, or amine groups bonded to the chemically functionalized planarization pad as functional groups. In other examples, any other suitable chemically functionalized planarization pad can be used.

Further, the disclosure comprises configurations according to the following examples.

According to Example 1, a planarization solution for abrasive-free planarization comprises a hydrolyzing agent, a first chelator, and a second chelator.

Example 2 includes the planarization solution of Example 1, wherein the planarization solution further comprises one or more corrosion inhibitors.

Example 3 includes the planarization solution of Example 1 or Example 2, wherein the one or more corrosion inhibitors comprise one or more of ammonium dodecyl sulfate, diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

Example 4 includes the planarization solution of any of Example 1 to Example 3, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 5 includes the planarization solution of any of Example 1 to Example 4, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 6 includes the planarization solution of any of Example 1 to Example 5, wherein a pH of the planarization solution is within a range of 1 to 13.

Example 7 includes the planarization solution of any of Example 1 to Example 6, wherein a pH of the planarization solution is within a range of 3 to 9.

According to Example 8, a method of planarizing a substrate comprising copper comprises removing copper from the substrate by contacting the substrate with a chemically functionalized planarization pad and a planarization solution, the planarization solution comprising a hydrolyzing agent, a first chelator, and a second chelator.

Example 9 includes the method of Example 8, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 10 includes the method of Example 8 or Example 9, wherein the planarization solution further comprises one or more corrosion inhibitors, wherein the one or more corrosion inhibitors comprise one or more of diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

Example 11 includes the method of any of Example 8 to Example 10, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 12 includes the method of any of Example 8 to Example 11, wherein the chemically functionalized planarization pad comprises one or more of carboxylic acid groups, sulfonyl groups, or amine groups bonded to the chemically functionalized planarization pad as functional groups.

According to Example 13, a chemical planarization system comprises a chemically functionalized planarization pad, a platen configured to support the chemically functionalized planarization pad, and a substrate holder configured to hold a substrate against a surface of the chemically functionalized planarization pad. The chemical planarization system further comprises a planarization solution introduction system comprising a planarization solution, the planarization solution introduction system configured to introduce the planarization solution onto the chemically functionalized planarization pad, the planarization solution comprising a hydrolyzing agent, a first chelator, and a second chelator.

Example 14 includes the chemical planarization system of Example 13, wherein the chemical planarization system further comprises a pad rinsing system configured to rinse the chemically functionalized planarization pad.

Example 15 includes the chemical planarization system of Example 13 or Example 14, wherein the planarization solution further comprises one or more corrosion inhibitors.

Example 16 includes the chemical planarization system of any of Example 13 to Example 15, wherein the one or more corrosion inhibitors comprise one or more of ammonium dodecyl sulfate, diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

Example 17 includes the chemical planarization system of any of Example 13 to Example 16, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 18 includes the chemical planarization system of any of Example 13 to Example 17, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

Example 19 includes the chemical planarization system of any of Example 13 to Example 18, wherein the chemically functionalized planarization pad comprises one or more of carboxylic acid groups, sulfonyl groups, or amine groups bonded to the chemically functionalized planarization pad as functional groups.

Example 20 includes the chemical planarization system of any of Example 13 to Example 19, wherein a pH of the planarization solution is within a range of 3 to 9.

It will be understood that the configurations and/or approaches described herein are example in nature, and that these specific embodiments or examples are not to be considered in a limiting sense, because numerous variations are possible. The specific routines or methods described herein can represent one or more of any number of strategies. As such, various acts illustrated and/or described can be performed in the sequence illustrated and/or described, in other sequences, in parallel, or omitted. Likewise, the order of the above-described processes can be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A planarization solution for abrasive-free planarization, the planarization solution comprising:
a hydrolyzing agent;
a first chelator; and
a second chelator.

2. The planarization solution of claim 1, further comprising one or more corrosion inhibitors.

3. The planarization solution of claim 2, wherein the one or more corrosion inhibitors comprise one or more of ammonium dodecyl sulfate, diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

4. The planarization solution of claim 3, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

5. The planarization solution of claim 1, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

6. The planarization solution of claim 1, wherein a pH of the planarization solution is within a range of 1 to 13.

7. The planarization solution of claim 1, wherein a pH of the planarization solution is within a range of 3 to 9.

8. A method of planarizing a substrate comprising copper, the method comprising:
removing copper from the substrate by contacting the substrate with a chemically functionalized planarization pad and a planarization solution, the planarization solution comprising a hydrolyzing agent, a first chelator, and a second chelator.

9. The method of claim 8, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

10. The method of claim 8, wherein the planarization solution further comprises one or more corrosion inhibitors, wherein the one or more corrosion inhibitors comprise one or more of diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

11. The method of claim 10, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

12. The method of claim 8, wherein the chemically functionalized planarization pad comprises one or more of carboxylic acid groups, sulfonyl groups, or amine groups bonded to the chemically functionalized planarization pad as functional groups.

13. A chemical planarization system, comprising:
a chemically functionalized planarization pad;
a platen configured to support the chemically functionalized planarization pad;
a substrate holder configured to hold a substrate against a surface of the chemically functionalized planarization pad; and
a planarization solution introduction system comprising a planarization solution, the planarization solution introduction system configured to introduce the planarization solution onto the chemically functionalized planarization pad, the planarization solution comprising a hydrolyzing agent, a first chelator, and a second chelator.

14. The chemical planarization system of claim 13, further comprising a pad rinsing system configured to rinse the chemically functionalized planarization pad.

15. The chemical planarization system of claim 13, wherein the planarization solution further comprises one or more corrosion inhibitors.

16. The chemical planarization system of claim 15, wherein the one or more corrosion inhibitors comprise one or more of ammonium dodecyl sulfate, diammonium phosphate, imidazole, 3-amino-1,2,4-triazole, 1,8-diazabicyclo[5.4.0]undec-7-ene, benzotriazole, 5-methyl-1H-benzotriazole, 3,5-diamino-1,2,4-triazole, adenine, 1H-purine, 3-amino-5-methylthio-1H-1,2,4-triazole, or 1,2,4-triazole.

17. The chemical planarization system of claim 16, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

18. The chemical planarization system of claim 13, wherein the first chelator comprises one of glycine, oxalic acid, citric acid, maleic acid, glutamic acid, L-alanine, or an amino acid, and the second chelator comprises one of glycine, oxalic acid, citric acid, maleic acid, glutamic acid, L-alanine, or an amino acid.

19. The chemical planarization system of claim 13, wherein the chemically functionalized planarization pad comprises one or more of carboxylic acid groups, sulfonyl groups, or amine groups bonded to the chemically functionalized planarization pad as functional groups.

20. The chemical planarization system of claim 13, wherein a pH of the planarization solution is within a range of 3 to 9.
